(19) United States
(12) Patent Application Publication
(10) Pub. No.: US 2008/0042277 A1
(43) Pub. Date: Feb. 21, 2008

(54) BGA package with leads on chip field of the invention

(75) Inventor: Hung-Tsun Lin, Tainan (TW)

Correspondence Address: TROXELL LAW OFFICE PLLC, SUITE 1404, 5205 LEESBURG PIKE, FALLS CHURCH, VA, 22041, US

(73) Assignees: ChipMOS Technologies (Bermuda) Ltd.; ChipMOS Technologies Inc.

(21) Appl. No.: 11/543,053

(22) Filed: Oct. 5, 2006

(30) Foreign Application Priority Data
Aug. 6, 2006 (CN) 095120350

(51) Int. Cl. H01L 23/48

(52) U.S. Cl. 257/738; 257/E23.069

(57) ABSTRACT

A BGA package primarily includes a plurality of leads from a leadless lead frame, a chip, and a die-attaching layer. The chip is electrically connected to the leads by a plurality of bonding wires. Solder balls are disposed at the ball placing regions of the leads. Encapsulant encapsulates the chip, the die-attaching layer, and the top surfaces, the bottom surfaces, and the sides of the leads so that the ball placing regions are embedded inside the encapsulant. A plurality of cavities are formed in the encapsulant to expose the corresponding ball placing regions to resolve the solderability of the solder balls and to enhance the stability and reliability of wire bonding and solder ball placing. In one embodiment, a die-attaching layer between the chip and the leads is patterned for elastically supporting the solder balls and for wire bonding.

### FIELD OF THE INVENTION

The present invention relates to a BGA (Ball Grid Array) package without printed circuit boards, and more particularly, to a BGA package with leads on a chip.

### BACKGROUND OF THE INVENTION

The conventional Ball Grid Array packages (BGA) are always using printed circuit boards as chip carriers. In one kind of BGA packages, the active surfaces of chips face the printed circuit boards, and the bonding wires pass through the slots of the printed circuit boards. This kind of BGA package is often called Window BGA, Chip-On-Board BGA, or Chip-On-Substrate BGA.

As shown in FIG. 1, a conventional BGA package 100 includes a printed circuit board 110, a chip 120, a die-attaching layer 130, a plurality of bonding wires 140, an encapsulant 150, and a plurality of solder balls 160. The printed circuit board 110 is made of BT (Bismaleimide Triazine resin) which has a top surface 111, a bottom surface 112, a slot 113 penetrating the top surface 111 and the bottom surface 112, a plurality of bonding fingers, and a plurality of ball pads, not shown in the figure. A plurality of bonding pads 40 are formed on the active surface 121 of the chip 120. The active surface 121 of the chip 120 is attached to the top surface 111 of the printed circuit board 110 by the die-attaching layer 130 so that the bonding pads 122 are aligned in the slot 113. The bonding pads 122 of the chip 120 are electrically connected to the printed circuit board 110 by the bonding wires 140 through the slot 113. The encapsulant 150 is formed on the top surface 111 of the printed circuit board 110 as well as in the slot 113 to encapsulate the chip 120 and the bonding wires 140. The solder balls 160 are disposed on the bottom surface 112 of the printed circuit board 110 as external terminals. Since the active surface 121 of the chip 120 is close to the printed circuit board 110, the lengths of the bonding wires 140 can be shortened so that it can be implemented in the packages of high-frequency memories such as DDR (Double Data Rate) II or other ASIC (Application Specific Integrated Circuit).

However, the cost of the printed circuit board is much higher than the one of a lead frame and the reliability against moisture is also low. If a lead frame can be used as a chip carrier to assembly as a BGA package, the cost can be greatly reduced. Related leadframe-based BGA packages using lead frames as chip carriers have been revealed in R.O.C. Taiwan Patent No. 495941 and 584316. However, the solder balls are totally exposed outside the package without any protection which leads to the falling of the solder balls during shipping, handling, and storage. Moreover, the solder balls are lack of support during wire-bonding and ball-placing, the stability of solder ball placement and the reliability of the packages require further improvement.

### SUMMARY OF THE INVENTION

The main purpose of the present invention is to provide a BGA package using a leadless lead frame as a chip carrier, to resolve the solderability of the solder balls and to enhance the stability and reliability of the wire bonding and solder ball placement.

The second purpose of the present invention is to provide a BGA package using a leadless lead frame as a chip carrier, to assemble a chip with center bonding pads or/and peripheral bonding pads.

The third purpose of the present invention is to provide a BGA package using a leadless lead frame as a chip carrier, to enhance the stress resistance of the solder balls.

The fourth purpose of the present invention is to provide a BGA package using a leadless lead frame as a chip carrier, to minimize the package dimension to become a Chip Scale Package (CSP).

According to the invention, a BGA package, using a leadless lead frame as a chip carrier, primarily includes a leadless lead frame, a chip, a die-attaching layer, a plurality of bonding wires, an encapsulant, and a plurality of solder balls. The leadless lead frame has a plurality of leads wherein each lead has a defined bottom surface including a wire bonding region and a ball placing region. The chip has an active surface where a plurality of first bonding pads are formed on the active surface. The die-attaching layer is formed between the active surface of the chip and the top surfaces of the leads. The first bonding pads of the chip are electrically connected to the wire bonding regions of the leads by the bonding wires. The encapsulant encapsulates the chip, the bonding wires, the die-attaching layer, and the top surfaces, the bottom surfaces and the sides of the leads except the ball placing regions. Moreover, a plurality of cavities are formed in the footprint surface of the encapsulant to expose the ball placing regions. The solder balls are disposed at the ball placing regions.

### DESCRIPTION OF THE DRAWINGS

FIG. 1 shows a cross sectional view of a conventional BGA package.

FIG. 2 shows a cross sectional view of a BGA package according to the first embodiment of the present invention.

FIG. 3 shows a bottom view of a die-attaching layer on chip in the BGA package according to the first embodiment of the present embodiment.

FIG. 4 shows a cross sectional view of a BGA package according to the second embodiment of the present invention.

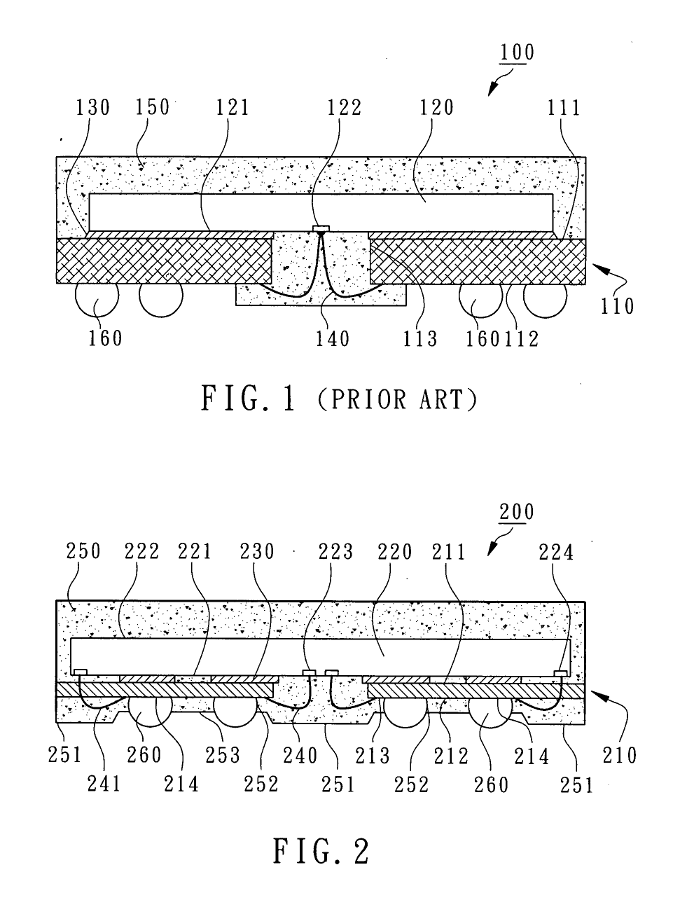

### DETAIL DESCRIPTION OF THE INVENTION

Please refer to the attached drawings, the present invention will be described by means of embodiment(s) below.

A BGA package with leads on a chip is disclosed according to the first embodiment. As shown in FIG. 2, a BGA package 200 primarily includes a leadless lead frame having a plurality of leads 210, a chip 220, a die-attaching layer 230, a plurality of bonding wires 240 and 241, an encapsulant 250, and a plurality of solder balls 260. The plurality of leads 210 have external ends aligned to the edges of the encapsulant 250. Normally, the materials of the leads 210 are metals such as copper, iron, or its alloys and are formed by punching or etching. Each lead 210 has a top surface 211 and a bottom surface 212 where each bottom surface 212 includes a wire bonding region 213 and a ball placing region 214 defined for bonding the bonding wires 240 and for placing the solder balls 260 respectively.

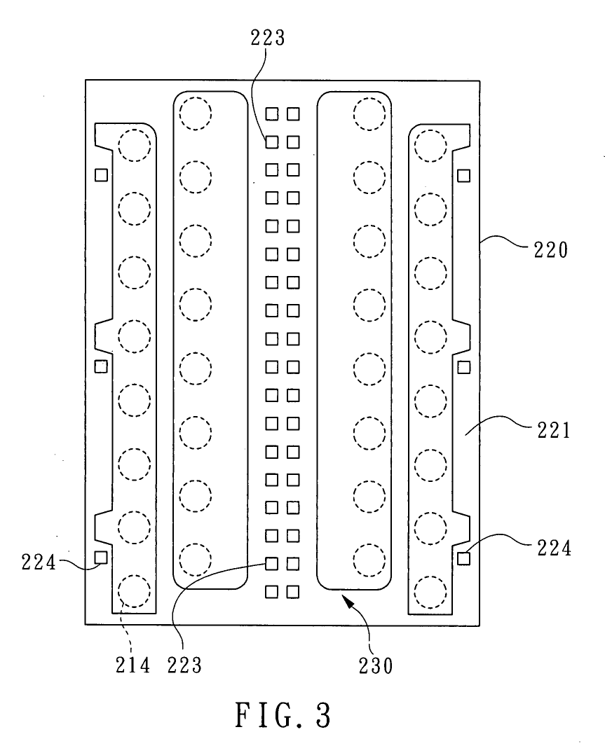

The chip 220 has an active surface 221 and a corresponding back surface 222 where a plurality of first bonding pads 223 are formed on the active surface 222. In the present embodiment, the first bonding pads 223 are disposed at a center of the active surface 221, and the chip 220 further has at least one second bonding pad 224 formed at a periphery of the active surface 221. The patterned die-attaching layer 230 doesn't cover the second bonding pad 224 (as shown in FIG. 3). Since there are gaps between leads 210 and adjacent leads 210 without covering the second bonding pad 224, therefore, there is no needs for via holes.

The die-attaching layer 230 is formed between the active surface 221 of the chip 220 and the top surfaces 211 of the leads 210 where its die-attaching area on some portions of the top surfaces 211 is aligned with the wire bonding regions 213 and the ball placing regions 214. The die-attaching layer 230 may be a B-stage printed paste or a die-attaching film which is pre-formed on the active surface 221 of the chip 220 or on the top surfaces 221 of the leads 210. In the present embodiment, the die-attaching layer 230 is pre-printed on the active surface 221 of the chip 220. Preferably, as shown in FIG. 3, the die-attaching layer 230 is patterned so that the die-attaching region includes the corresponding wire bonding regions 213 and the corresponding ball placing regions 214 of the leads 210 without covering the first bonding pads 223 and the second bonding pad 224. Therefore, the die-attaching layer 230 can enhance the bonding of the bonding wires 240 and the placement of the solder balls 260. Moreover, the die-attaching layer 230 can further enhance the complete encapsulation of the leads of the encapsulant 250. Preferably, the die-attaching layer 230 is a low modulus elastomer which can elastically support the bonding wires 240 and the solder balls 260 to increase the stress resistance of the solder balls 260.

The first bonding pads 223 of the chip 220 are electrically connected to the corresponding bonding region 213 of the leads 210 by the bonding wires 240, the second bonding pad 224 to the leads 210 by the bonding wires 241. The encapsulant 250 encapsulates the chip 220, the bonding wires 240 and 241, the die-attaching layer 230, the top surfaces 211, the bottom surfaces 212 and the sides of the leads 210 between the top surfaces 211 and the bottom surfaces 212 except the ball placing regions 214. Furthermore, a plurality of cavities 252 are formed in the footprint surface 251 of the encapsulant 250 to expose the corresponding ball placing regions 214 to protect the bottom of the solder balls 260 to prevent falling of the solder balls. In the present embodiment, after encapsulation, a plurality of cavities 252 are formed in the footprint surface 251 of the encapsulant 250 by half-etching the lead frame so that the ball placing regions 214 can be exposed from the footprint surface 251 of the encapsulant 250. In the present embodiment, the encapsulant 250 has at least a recession 253 which is lower than the footprint surface 251 of the encapsulant 250 where the cavities 252 are located within the recession 253 to maintain the stand-off heights of the solder balls 260.

Furthermore, the encapsulant 250 can completely encapsulates the chip 220 or partially encapsulates the chip 220 to expose the back surface 222 of the chip, depending on the package types. In the present embodiment, the active surface 221 of the chip 220 is not smaller than 70% of the footprint surface 251 of the encapsulant 250 so that the chip 220 becomes a Chip Scale Package (CSP), moreover, all the solder balls 260 are disposed under the chip 220 and supported by the die-attaching layer 230.

Furthermore, solder balls 260 can be disposed on the ball placing regions 214 by solder paste printing or solder ball placement. The layout of the solder balls 260 can be the same as the one of the conventional window BGA package 100.

Therefore, the leadless lead frame is used as a chip carrier in the BGA package 200 to resolve the solderability of solder balls and to enhance the stability and the reliability of wire bonding and solder ball placing. Moreover, the chip 220 with both central and peripheral bonding pads can be assembled with a leadless lead frame to become a BGA package.

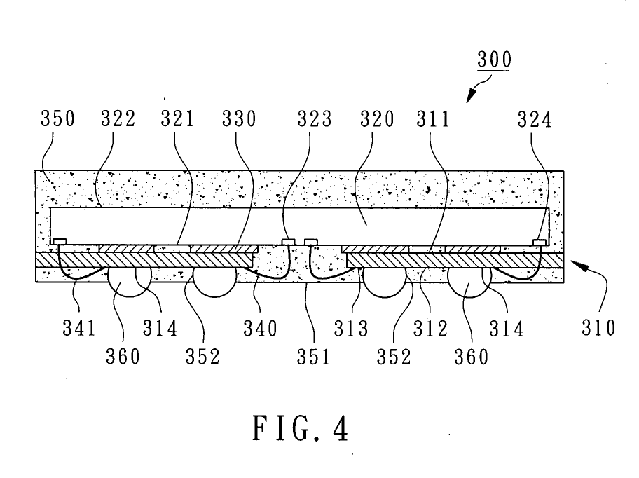

In the second embodiment of the present invention, another BGA package is revealed. As shown in FIG. 4, the package 300 includes a leadless lead frame, a chip 320, a die-attaching layer 330, a plurality of bonding wires 340, an encapsulant 350, and a plurality of solder balls 360. The major components are about the same as the first embodiment. The leadless lead frame has a plurality of leads 310 where each lead 310 has a top surface 311 and a bottom surface 312. A wire bonding region 313 and a ball placing region 314 are defined on each bottom surface 312. The chip 320 has an active surface 321 and a back surface 322 where a plurality of first bonding pads 323 and at least a second bonding pad 324 are formed at the center and the periphery of the active surface 321 respectively. The die-attaching layer 330 is formed between the active surface 321 of the chip 320 and the top surfaces 311 of the leads 310, meaning that the leads 310 are disposed on the chip 320. The first bonding pads 323 and the second bonding pad 324 of the chip 320 are electrically connected to the corresponding wire bonding regions 313 of the leads 310 by the bonding wires 340 and 341 respectively. The encapsulant 350 encapsulates the chip 320, the bonding wires 340, the die-attaching layer 330, the top surfaces 311, the bottom surfaces 312 and the sides of the leads 310 except the ball placing regions 314. A plurality of cavities 352 are formed in the footprint surface 351 of the encapsulant 350 to expose the corresponding ball placing regions 314 of the leads 310. In the present embodiment, the footprint surface 351 of the encapsulant 350 can be flat and lower than the bottom surfaces 312 of the leads 310. Furthermore, the solder balls 360 are disposed on the ball placing regions 314 so that the solderability of the solder balls 360 and the stability and the reliability of wire bonding and solder ball placing can be enhanced by using a leadless lead frame as a chip carrier.

The above description of embodiments of this invention is intended to be illustrative and not limiting. Other embodiments of this invention will be obvious to those skilled in the art in view of the above disclosure.

1. A BGA package comprising:
a plurality of leads wherein each lead has a bottom surface including a wire bonding region and a ball placing region defined;
a chip having an active surface wherein a plurality of first bonding pads are formed on the active surface;
a die-attaching layer formed between the active surface of the chip and top surfaces of the leads;
a plurality of bonding wires connecting the first bonding pads of the chip to the wire bonding regions of the leads;
an encapsulant encapsulating the chip, the bonding wires, the die-attaching layer, and the top surfaces, the bottom surfaces and sides of the leads between the top surfaces and the bottom surfaces except the ball placing regions, wherein a plurality of cavities are formed in a footprint surface of the encapsulant to expose the corresponding ball placing region; and
a plurality of solder balls disposed at the ball placing regions, wherein the cavities are formed by etching the ball placing regions of the leads.

2. (canceled)

3. The BGA package claim 1, wherein the die-attaching layer is patterned so as to elastically support the wire bonding regions and the ball placing regions.

4. The BGA package of claim 3, wherein the chip further has at least a second bonding pad formed at a periphery of the active surface, the first bonding pads are located at a center of the active surface, the patterned die-attaching layer does not cover the second bonding pad.

5. The BGA package of claim 1, wherein the die-attaching layer is a low modulus elastomer.

6. The BGA package of claim 1, wherein the active surface of the chip is not smaller than 70% of the footprint surface of the encapsulant so that the BGA package is a Chip Scale Package.

7. The BGA package of claim 1, wherein the encapsulant further has at least a recession lower than the footprint surface of the encapsulant, the cavities are located within the recession.
